(19) United States
(12) Patent Application Publication
(10) Pub. No.: US 2013/0048344 A1
(43) Pub. Date: Feb. 28, 2013

(54) HIGH FREQUENCY CIRCUIT BOARD

(71) Applicant: CHOON LEONG LOU, HSINCHU CITY (TW)

(72) Inventor: CHOON LEONG LOU, HSINCHU CITY (TW)

(73) Assignee: STAR TECHNOLOGIES INC., HSINCHU CITY (TW)

(21) Appl. No.: 13/220,825

(22) Filed: Aug. 30, 2011

(51) Int. Cl. H05K 1/11

(52) U.S. Cl. 174/251

(57) ABSTRACT

In one embodiment of the present invention, a high frequency circuit board includes a laminate having a top surface with a groove; a semi-rigid cable positioned in the groove of the laminate; and a passivation layer filling the groove; wherein the semi-rigid cable is configured to transmit a high frequency signal, and the semi-rigid cable comprises a central conductor, an outer conductor, and an insulating layer between the central conductor and the outer conductor.

### BACKGROUND OF THE INVENTION

1. Technical Field

The present invention relates to a high frequency circuit board, and more particularly, to a high frequency circuit board equipped with semi-rigid coaxial cable for transmitting high frequency signal.

2. Background

Circuits used in many electronic devices, for example, cellular phones and radios, produce, receive, or function with high frequency signals as well as low frequency signals. Integration of high and low frequency circuits typically involve the use of hybrid substrates, with low frequency devices formed on FR4 and high frequency devices formed on ceramics. Both the low and high frequency signals may be transmitted across a substrate or printed circuit board by metal traces; however, while low frequency signals may be transmitted along a single metal trace, the high frequency signal is typically transmitted by multiple metal traces which form a waveguide structure, such as a microstrip or coplanar trace.

FIG. 1 is a high frequency circuit board 10 according to the prior art. The conventional high frequency circuit board 10 includes a signal line 11, two dielectric layers 13, 15, and two metal layers 17, 19. The two metal layers 17, 19, serving as the ground lines, are used to prevent the signal transmission line 11 from being influenced by EMI (Electromagnetic interference) of the other circuit components. However, the overall impedance of the high frequency circuit board 10 depends on the thickness (T1, T2) of the two dielectric layers 13, 15, i.e., the thickness (T1, T2) of the two dielectric layers 13, 15 must be precisely controlled to meet the high frequency application requirement. U.S. Pat. No. 5,82,855 and U.S. Pat. No. 6,717,494 both disclose high frequency circuit boards operating at high speed and high frequency.

### SUMMARY

One aspect of the present invention provides a high frequency circuit board equipped with semi-rigid coaxial cable for transmitting high frequency signal.

A high frequency circuit board according to this aspect of the present invention comprises a laminate having a top surface with a groove; a semi-rigid cable positioned in the groove of the laminate; and a passivation layer filling the groove; wherein the semi-rigid cable is configured to transmit a high frequency signal, and the semi-rigid cable comprises a central conductor, an outer conductor, and an insulating layer between the central conductor and the outer conductor.

A high frequency circuit board according to another aspect of the present invention comprising a bottom laminate stack; a top laminate stack; and a semi-rigid cable sandwiched between the bottom laminate stack and the top laminate stack, wherein the semi-rigid cable is configured to transmit a high frequency signal, and the semi-rigid cable comprises a central conductor, an outer conductor, and an insulating layer between the central conductor and the outer conductor.

To transmit high frequency signal in the printed circuit board, the conventional technique uses two metal layers to prevent the signal line from being influenced by EMI of the other electronic components and uses two dielectric layer to electrically isolate the signal line from the two metal layers, and this technique has shortage in that the overall impedance of the high frequency circuit board depends on the thickness (T1, T2) of the two dielectric layers.

In contrast, the embodiment of the present invention uses the semi-rigid cable to transmit the high frequency signal in the printed circuit board, wherein the semi-rigid cable can be bent to be embedded inside the laminates of the printed circuit board due to its semi-rigid property, and the characteristic impedance (Z₀) of the semi-rigid cable is substantially independent of the environment where it is used. Consequently, the semi-rigid cable can be used to transmit the high frequency signal in the printed circuit board directly substantially without being influenced by the thickness of the laminate (dielectric layer) of the printed circuit board.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention are illustrated with the following description and upon reference to the accompanying drawings in which:

FIG. 1 is a high frequency circuit board according to the prior art;

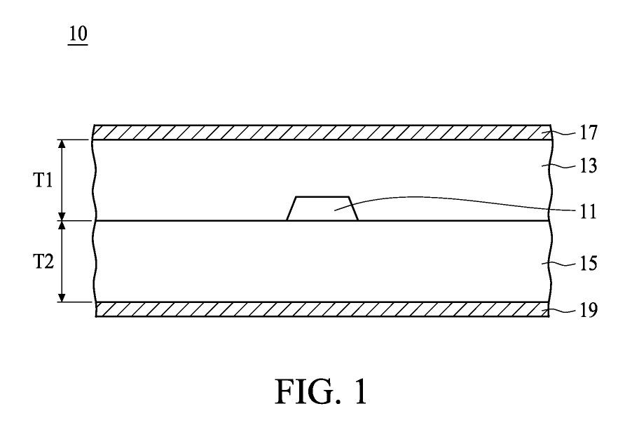

FIG. 2 is a top view of a high frequency circuit board according to one embodiment of the present invention;

FIG. 3 is a cross-sectional view of the high frequency circuit board alone cross-sectional line 1-1 in FIG. 2 according to one embodiment of the present invention;

FIG. 4 illustrates the cross-sectional structure of the semi-rigid cable according to one embodiment of the present invention;

FIG. 5 is a disassembled view of a high frequency circuit board according to one embodiment of the present invention; and

FIG. 6 is a cross-sectional view of the high frequency circuit board along the cross-sectional line 2-2 according to one embodiment of the present invention.

### DETAILED DESCRIPTION

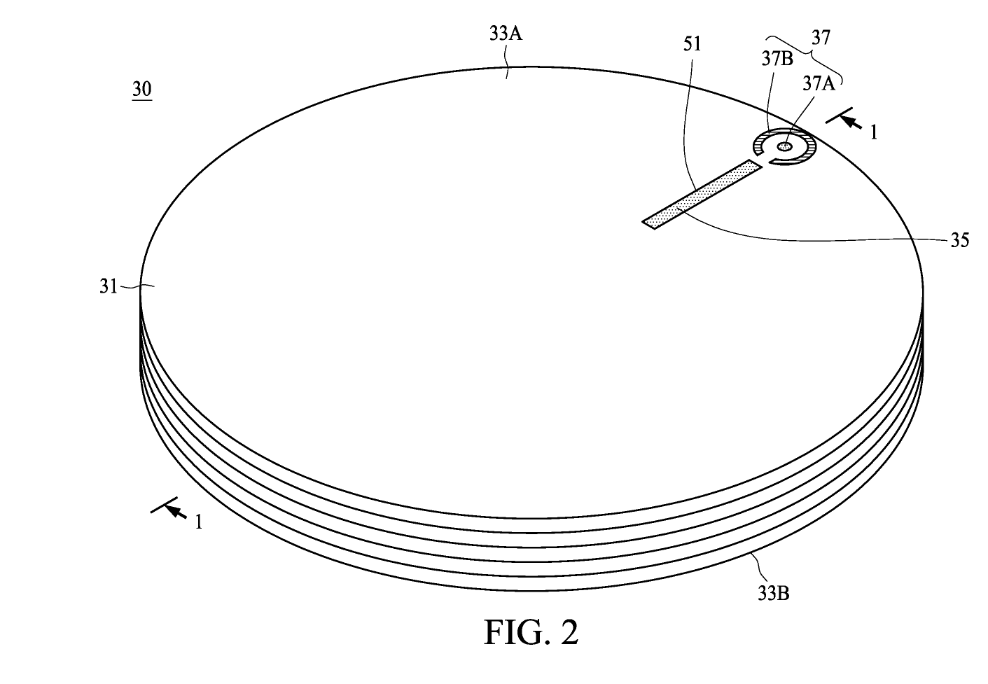

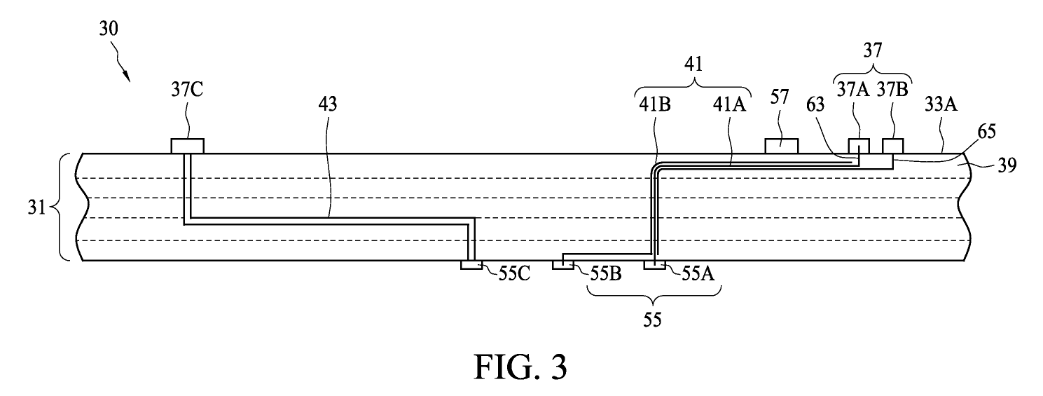

FIG. 2 is a top view of a high frequency circuit board 30 according to one embodiment of the present invention, and FIG. 3 is a cross-sectional view of the high frequency circuit board 30 along the cross-sectional line 1-1 according to one embodiment of the present invention. In one embodiment of the present invention, the high frequency circuit board 30 comprises a laminate 31 having a top surface 33A with a groove 35 and a bottom surface 33B, a semi-rigid cable 41 positioned in the groove 35 of the laminate 31, and a passivation layer 51 filling the groove 35.

In one embodiment of the present invention, the semi-rigid cable 41 is configured to transmit a high frequency signal, one end of the semi-rigid cable 41 is connected to a composite connecting structure 37 including a signal pad 37A and a ground pad 37B, and the other end of the semi-rigid cable 41 is connected to a composite connecting structure 55 including a signal pad 55A and a ground pad 55B. In one embodiment of the present invention, the ground pad 37B substantially surrounds the signal pad 37A, and the ground pad 55B substantially surrounds the signal pad 55A.

In particular, the semi-rigid cable 41 can be bent to be embedded inside the laminate 31 due to its semi-rigid property. In one embodiment of the present invention, the semi-rigid cable 41 comprises a horizontal portion 41A positioned in the laminate 31, and an angled corner 41B connected to the horizontal portion 41A, wherein the horizontal portion 41A can be disposed in the uppermost or the bottommost layer of the laminate 31.

In one embodiment of the present invention, the semi-rigid cable 41 is embedded inside the groove 35 of the laminate 31, and the passivation layer 51 fills the groove 35; therefore, the circuit components 57 such as the pads, capacitors, resistors can be placed at certain locations of the top surface 33A right on the horizontal portion 41A of the semi-rigid cable 41, i.e., right on the passivation layer 51. Similarly, the semi-rigid cable 41 does not substantially occupy the bottom surface 33B of the laminate 31, and the circuit components 59 can be placed at certain locations of the bottom surface 33B right below the horizontal portion 41A of the semi-rigid cable 41.

In one embodiment of the present invention, the laminate 31 includes a plurality of layers 39 made of dielectric epoxy glass known as FR4 for electrically isolating the conductive line 43, which is formed based upon a predetermined pattern. In addition, at certain locations on the circuit board 30, conductive pads 37C are formed to electrically connect the conductive line 43. In one embodiment of the present invention, the conductive line 43 is configured to transmit a low frequency signal.

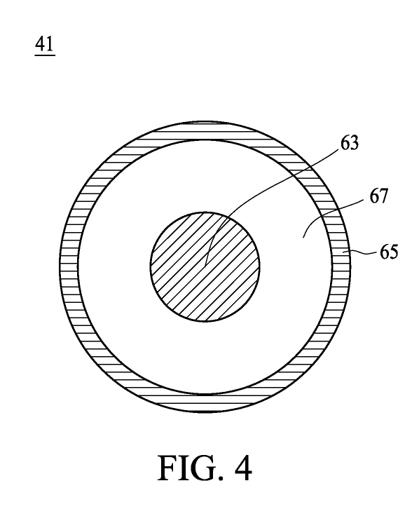

FIG. 4 illustrates the cross-sectional structure of the semi-rigid cable 41 according to one embodiment of the present invention. In one embodiment of the present invention, the semi-rigid cable 41 comprises a central conductor 63, an outer conductor 65, and an insulating layer 67 between the central conductor 63 and the outer conductor 65. In one embodiment of the present invention, the diameter of the semi-rigid cable 41 is smaller than 0.3 mm. In one embodiment of the present invention, the characteristic impedance (Z₀) of the semi-rigid cable 41 is substantially independent of the environment where it is used. Consequently, the semi-rigid cable 41 can be used to transmit the high frequency signal in the laminate 30 directly substantially without being influenced by the thickness of the laminate 39 (dielectric layer) of the laminate 31. In one embodiment of the present invention, the central conductor 63 comprises copper, the outer conductor 65 comprises copper or nickel, the insulating layer 67 comprises PTFE (Polytetrafluoroethene), and the semi-rigid cable 41 does not have an outer insulating layer covering the outer conductor 65.

In one embodiment of the present invention, the laminate 31 comprises a plurality of bottom pads 55A-55C on the bottom surface 33B. In one embodiment of the present invention, the central conductor 63 connects the top signal pad 37A on the top surface 33A and the bottom signal pad 55A on the bottom surface 33B, the outer conductor 65 connects the top ground pad 37B on the top surface 33A and the bottom ground pad 55B on the bottom surface 33B, and the conductive line 43 connects the signal pad 37C on the top surface 33A and the bottom pad 55C on the bottom surface 33B.

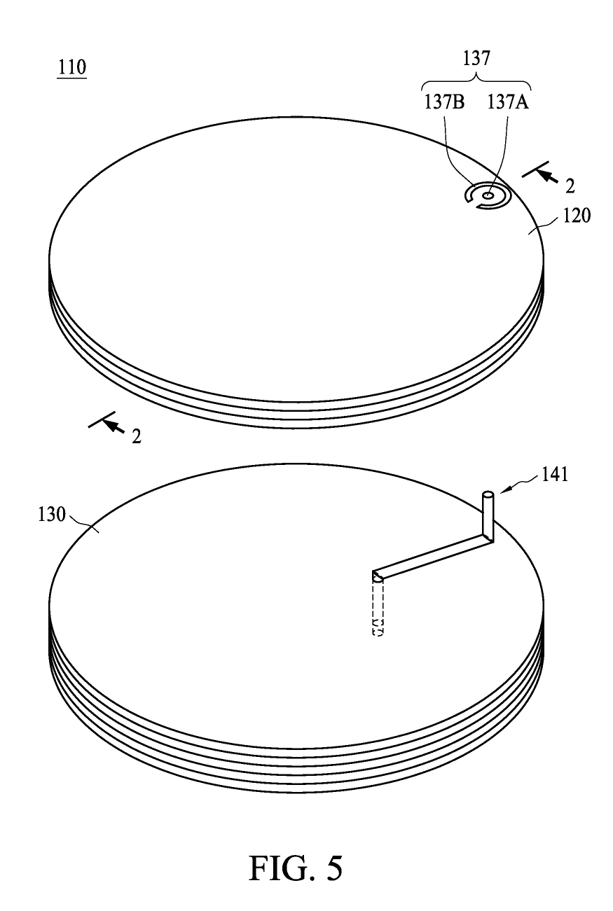

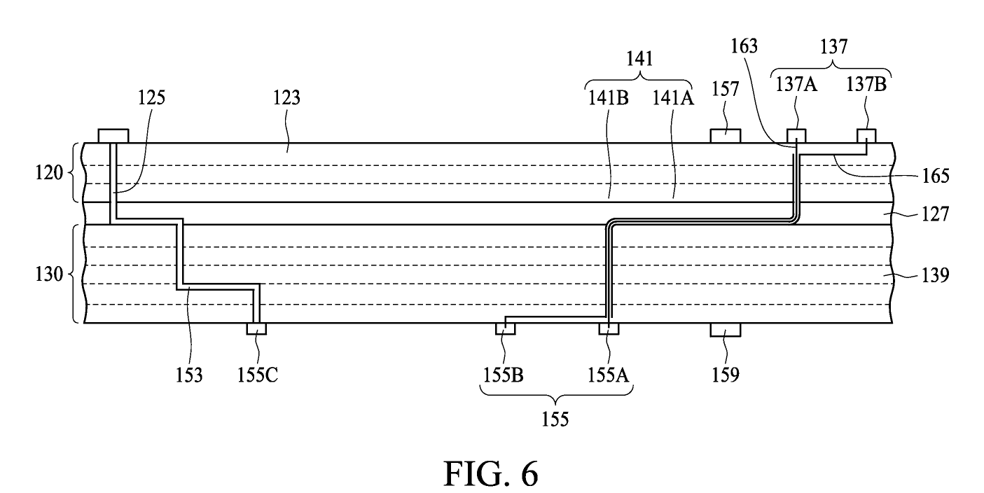

FIG. 5 is a disassembled view of a high frequency circuit board 110 according to one embodiment of the present invention, and FIG. 6 is a cross-sectional view of the high frequency circuit board 110 along the cross-sectional line 2-2 according to one embodiment of the present invention. In one embodiment of the present invention, the high frequency circuit board 110 comprises a bottom laminate stack 130 and a top laminate stack 120, a semi-rigid cable 141 sandwiched between the bottom laminate stack 130 and the top laminate stack 120. In one embodiment of the present invention, the top laminate stack 120 is adhered to the bottom laminate stack 130 by an intervening adhesive layer 127, and the semi-rigid cable 141 is embedded in the intervening adhesive layer 127. In one embodiment of the present invention, the bottom laminate stack 130 has a groove, the semi-rigid cable 141 is positioned in the groove, and a passivation layer fills the groove.

In one embodiment of the present invention, the semi-rigid cable 141 is the same as that disclosed in FIG. 4 and configured to transmit a high frequency signal, one end of the semi-rigid cable 141 is connected to a composite connecting structure 137 including a signal pad 137A and a ground pad 137B, and the other end of the semi-rigid cable 41 is connected to a composite connecting structure 155 including a signal pad 155A and a ground pad 155B. In one embodiment of the present invention, the ground pad 137B substantially surrounds the signal pad 137A, and the ground pad 155B substantially surrounds the signal pad 155A.

In one embodiment of the present invention, the diameter of the semi-rigid cable 141 is smaller than 0.3 mm. In particular, the semi-rigid cable 141 can be bent to be embedded inside the laminate stack 130 due to its semi-rigid property. In one embodiment of the present invention, the semi-rigid cable 141 comprises a horizontal portion 141A positioned in the circuit board 110, and a substantially right-angled corner 141B connected to the horizontal portion 141A. In one embodiment of the present invention, the characteristic impedance (Z₀) of the semi-rigid cable 141 is substantially independent of the environment where it is used. Consequently, the semi-rigid cable 141 can be used to transmit the high frequency signal in the bottom laminate stack 130 and the top laminate stack 120 directly substantially without being influenced by the thicknesses of the laminate 139 (dielectric layer) of the laminate stack 130 or the laminate 123 (dielectric layer) of the laminate stack 120.

In one embodiment of the present invention, the semi-rigid cable 141 is embedded between the top laminate stack 120 and the bottom laminate stack 130 substantially without occupying the top surface of the top laminate stack 120; therefore, the circuit components 157 such as the pads, capacitors, resistors can be placed at certain locations of the top surface of the top laminate stack 120 right on the horizontal portion 141A of the semi-rigid cable 41. Similarly, the semi-rigid cable 141 is embedded between the top laminate stack 120 and the bottom laminate stack 130 substantially without occupying the bottom surface of the bottom laminate stack 130; therefore, the circuit components 159 can be placed at certain locations of the bottom surface of the bottom laminate stack 130 right below the horizontal portion 141A of the semi-rigid cable 41.

To transmit high frequency signal in the printed circuit board, the conventional technique uses two metal layers to prevent the signal line from being influenced by EMI of the other electronic components and uses two dielectric layers to electrically isolate the signal line from the two metal layers, and this technique has shortage in that the overall impedance of the high frequency circuit board depends on the thickness (T1, T2) of the two dielectric layers.

In contrast, the embodiment of the present invention uses the semi-rigid cable to transmit the high frequency signal in the printed circuit board, the semi-rigid cable can be bent to be embedded inside the laminates of the printed circuit board due to its semi-rigid property, and the characteristic impedance (Z₀) of the semi-rigid cable is substantially independent of the environment where it is used. Consequently, the semi-rigid cable can be used to transmit the high frequency signal in printed circuit board directly substantially without being influenced by the thickness of the laminate (dielectric layer) of the printed circuit board.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A high frequency circuit board, comprising:
a laminate having a top surface with a groove;
a semi-rigid cable positioned in the groove of the laminate; and
a passivation layer filling the groove;
wherein the semi-rigid cable is configured to transmit a high frequency signal, and the semi-rigid cable comprises a central conductor, an outer conductor, and an insulating layer between the central conductor and the outer conductor.

2. The high frequency circuit board of claim 1, further comprising a signal pad connected to the central conductor of the semi-rigid cable and a ground pad connected to the outer conductor of the semi-rigid cable.

3. The high frequency circuit board of claim 1, wherein the semi-rigid cable comprises a horizontal portion positioned in the laminate.

4. The high frequency circuit board of claim 1, wherein the semi-rigid cable comprises an angled corner.

5. The high frequency circuit board of claim 1, wherein the laminate includes a conductive line configured to transmit a low frequency signal.

6. The high frequency circuit board of claim 1, wherein the semi-rigid cable does not have an outer insulating shell covering the outer conductor.

7. The high frequency circuit board of claim 1, wherein the semi-rigid cable is connected to a composite connecting structure including a signal pad and a ground pad, and the ground pad substantially surrounds the signal pad.

8. A high frequency circuit board, comprising:
a bottom laminate stack;
a top laminate stack; and
a semi-rigid cable sandwiched between the bottom laminate stack and the top laminate stack, wherein the semi-rigid cable is configured to transmit a high frequency signal, and the semi-rigid cable comprises a central conductor, an outer conductor, and an insulating layer between the central conductor and the outer conductor.

9. The high frequency circuit board of claim 8, wherein the semi-rigid cable comprises a horizontal portion positioned on a top surface of the bottom laminate stack.

10. The high frequency circuit board of claim 8, wherein the semi-rigid cable comprises an angled corner.

11. The high frequency circuit board of claim 8, wherein the bottom laminate stack includes a conductive line configured to transmit a low frequency signal.

12. The high frequency circuit board of claim 8, further comprising an intervening adhesive layer configured to adhere the top laminate stack to the bottom laminate stack.

13. The high frequency circuit board of claim 8, wherein the semi-rigid cable does not have an outer insulating shell covering the outer conductor.

14. The high frequency circuit board of claim 8, wherein the semi-rigid cable is connected to a composite connecting structure including a signal pad and a ground pad, and the ground pad substantially surrounds the signal pad.
